(19) United States
(12) Patent Application Publication
(10) Pub. No.: US 2015/0028441 A1
(43) Pub. Date: Jan. 29, 2015

(54) SEMICONDUCTOR ELEMENT WITH SOLDER RESIST LAYER

(71) Applicant: Siemens Aktiengesellschaft, Munich (DE)

(72) Inventor: Christian SCHRÖTER, Bamberg (DE)

(21) Appl. No.: 14/333,586

(22) Filed: Jul. 17, 2014

(30) Foreign Application Priority Data
Jul. 25, 2013 (DE) 102013214575.6

(51) Int. Cl. H01L 31/0296; H01L 31/18

(52) U.S. Cl. CPC H01L 31/0296; H01L 31/1828
USPC 257/431; 257/614; 438/597

(57) ABSTRACT

A semiconductor element includes a CdTe-based semiconductor material and a number of connection points of the semiconductor element to connect to electronic components. In at least one embodiment, the connection points are provided with a special solder resist layer including a mixture AB of at least two metals with different coefficients of expansion. In at least one embodiment, a radiation detector includes such a semiconductor element and optionally includes evaluation electronics for reading out a detector signal. In at least one embodiment, a medical technology device includes such a radiation detector. Furthermore, a method is disclosed for creating a semiconductor element which includes applying a solder resist layer to connection points. In at least one embodiment, the solder resist layer includes a mixture of at least two metals with different coefficients of expansion.

### PRIORITY STATEMENT

The present application hereby claims priority under 35 U.S.C. §119 to German patent application number DE 102013214575.6 filed Jul. 25, 2013, the entire contents of which are hereby incorporated herein by reference.

### FIELD

At least one embodiment of the invention generally relates to a semiconductor element with a CdTe-based semiconductor material and with a number of connection points of the semiconductor element to electronic components with a special solder resist layer, to a radiation detector with a number of such semiconductor elements and to a medical device with such a radiation detector. The invention further relates to a method for creation of a semiconductor element with such a solder resist layer.

### BACKGROUND

Solder processes are generally used for connecting semiconductor elements to electronic components. In these solder processes metallization are generally used at the connection points of the semiconductor element and the connection points of the electronic components. To connect these to each other, a soldering globule is briefly melted between these metallization. During cooling the solder material hardens again and by this process connects the two components. In this solder process parts of the metallization of the semiconductor elements or electronic components alloy with the solder and in this way establish a durable, electrically-conductive connection. If the metallization are completely dissolved during the soldering process, this can however also result in undesired direct contact between the between the solder and the semiconductor. As a result diffusions of foreign metal into the semiconductor frequently occur, which thus leads to a degradation of the component.

As a solution for this, so called UBM (“Under Bump Metallization”) has previously been deposited on the semiconductor at connection points of the semiconductor element, which on the one hand guarantee the electrical connection with the solder, on the other hand also protect the semiconductor in the sense of a solder resist layer from direct contact with the solder. Conventionally the metal nickel is used for the solder resist layer on account of its high melting temperature. With CdTe-based semiconductor elements the use of nickel as a material for the solder resist layer has previously resulted again and again in the solder resist layer detaching from the semiconductor element because of stresses between the different material layers, especially when layer thicknesses of a few micrometers are deposited.

Previous solutions for this problem were that a very thin nickel layer was used as the solder resist layer or a specific solder material, e.g. In solder, was used. The solder does not detach the Ni layer as much for example, but brings other problems with it, such as little flexibility in the choice of solder for example.

### SUMMARY

At least one embodiment of the present invention provides a semiconductor element with a CdTe-based semiconductor material which brings with it an advantageous solder resist property in conjunction with the semiconductor material and the greatest possible diversity of solder materials. A radiation detector is provided in an embodiment, and also a medical technology device with an improved semiconductor element is provided in an embodiment. In an embodiment, a method for creating such a semiconductor element is p[rovided, especially a specific solder resist layer in a semiconductor element.

The inventive semiconductor element of at least one embodiment includes a CdTe-based semiconductor material (such as CdTe or CZT for example). Such semiconductor elements, unlike Si semiconductor elements, are especially susceptible to the detaching phenomena mentioned here with thicker solder resist layers made of nickel since, as a result of the unusual coefficient of expansion of the CdTe-based semiconductor material, stresses can increasingly occur. If for example nickel is vapor-deposited at high temperature on the semiconductor material, stresses mostly occur during cooling down to room temperature if the layer thickness is too great. If on the other hand nickel is deposited at room temperature, whereby no stresses arise during the application of the solder resist layer, stresses still occasionally occur during operation because of the high temperature then arising.

At least one embodiment of the inventive radiation detectors are suitable, because of the advantages mentioned here, and especially on account of the improvement of the solder connections even in conventional usage conditions, for use in medical technology devices, and especially in devices with a counting rate detection under x-ray and/or gamma radiation, especially with high radiation intensity. Therefore the invention is also directed to a medical technology device with an inventive radiation detector, such as a flat-panel detector for example (e.g. for angiography devices). Especially preferred examples for this are x-ray systems, gamma radiation systems, CT systems or radionuclide emission tomography systems such as PET (Positron Emission Tomography) systems or SPECT (single photon emission CT) systems.

In accordance with at least one embodiment of the invention the semiconductor element can be created by a method comprising at least the step of applying a solder resist layer to connection points of the semiconductor element, wherein the solder resist layer includes a mixture of at least two metals with different coefficients of expansion. The material mixture of the solder resist layer enables a semiconductor element to be created by this method which has very low or no stresses in relation to the semiconductor material in a relevant temperature range of around 20° C. to around 150° C.

### BRIEF DESCRIPTION OF THE DRAWINGS

The invention will be explained in greater detail below on the basis of example embodiments which refer to the enclosed drawings. In this case the drawings are merely intended to illustrate the invention but the invention is not to be restricted to said drawings. In the figures:

FIG. 1 shows a schematic diagram of an embodiment of an inventive semiconductor element with a solder resist layer based on an alloy A/B,

FIG. 2 shows a schematic diagram B of an alternative form of embodiment of an inventive solder resist layer with a multilayer solder resist layer,

FIG. 3 shows a schematic structure of an embodiment of an inventive radiation detector and

FIG. 4 shows a schematic structure of an embodiment of a medical technology device.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The inventive semiconductor element of at least one embodiment includes a CdTe-based semiconductor material (such as CdTe or CZT for example). Such semiconductor elements, unlike Si semiconductor elements, are especially susceptible to the detaching phenomena mentioned here with thicker solder resist layers made of nickel since, as a result of the unusual coefficient of expansion of the CdTe-based semiconductor material, stresses can increasingly occur. If for example nickel is vapor-deposited at high temperature on the semiconductor material, stresses mostly occur during cooling down to room temperature if the layer thickness is too great. If on the other hand nickel is deposited at room temperature, whereby no stresses arise during the application of the solder resist layer, stresses still occasionally occur during operation because of the high temperature then arising.

In order to minimize or to prevent the stresses arising because of the different coefficients of expansion of semiconductors and UBM during temperature fluctuations, especially during the process of applying the UBM, of hybridization (the term “hybridization” is used synonymously in this technical field with the soldering process) or also in operation, the solder resist layer in at least one embodiment of an inventive semiconductor element contains a mixture AB of at least two metals with different coefficients of expansion. A or B here only stands for a placeholder for a metal selected from the periodic system of the elements. The solder resist layer including the at least two metals makes it possible, in at least one embodiment of the inventive semiconductor element, that only very small or no stresses to the semiconductor material occur in a relevant temperature range of around 20° C. to around 150° C. This prevents the degradation or deterioration of the components during the fabrication process, the hybridization or also in operation.

The solder resist layer in this case is provided in at least one embodiment of the inventive semiconductor element at the connection points of the semiconductor element, wherein the semiconductor element has a number of (i.e. one or more (e.g. 2, 3, 4, etc.), but also many) such connection points to connect the semiconductor element to electronic components.

These advantages and further advantages of at least one embodiment of the inventive semiconductor element make it suitable for use in radiation detectors and especially in detectors for counting rate detection of x-ray and/or gamma radiation. Therefore at least one embodiment of the invention is also directed to a radiation detector with a number of inventive semiconductor elements. Optionally the radiation detector can also have evaluation electronics to read out a detector signal, which can be embodied for example directly as a component of the radiation detector. As an alternative the evaluation electronics can also be embodied as a separate system able to be connected to the radiation detector.

At least one embodiment of the inventive radiation detectors are suitable, because of the advantages mentioned here, and especially on account of the improvement of the solder connections even in conventional usage conditions, for use in medical technology devices, and especially in devices with a counting rate detection under x-ray and/or gamma radiation, especially with high radiation intensity. Therefore the invention is also directed to a medical technology device with an inventive radiation detector, such as a flat-panel detector for example (e.g. for angiography devices). Especially preferred examples for this are x-ray systems, gamma radiation systems, CT systems or radionuclide emission tomography systems such as PET (Positron Emission Tomography) systems or SPECT (single photon emission CT) systems.

In accordance with at least one embodiment of the invention the semiconductor element can be created by a method comprising at least the step of applying a solder resist layer to connection points of the semiconductor element, wherein the solder resist layer includes a mixture of at least two metals with different coefficients of expansion. The material mixture of the solder resist layer enables a semiconductor element to be created by this method which has very low or no stresses in relation to the semiconductor material in a relevant temperature range of around 20° C. to around 150° C.

The dependent claims and also the subsequent description contain especially advantageous embodiments and developments of embodiments of the invention, wherein it is explicitly pointed out that at least one embodiment of the inventive radiation detector, at least one embodiment of the inventive medical technology device and at least one embodiment of the inventive method can also be further developed in accordance with the dependent claims for the semiconductor element and vice versa.

In a first embodiment, the inventive semiconductor element comprises a semiconductor material which is made up of semiconductor compounds which are preferably selected from the following group: CdTe, CdₓZn₁₋ₓTe (with 0≦x≦1) (so-called “CZT”), CdₓZn₁₋ₓTe_{y}Se_{1-y} (with 0≦x≦1; 0≦y≦1) und CdₓMn₁₋ₓTe_{y}Se_{1-y} (with 0≦x≦1; 0≦y≦1). In semiconductor materials preferably used for detectors, x has values between around 0.01 and around 0.3, further preferably between around 0.02 und 0.2. The value y lies in preferred semiconductor materials between 0.9 and 1. The coefficient of thermal expansion, also simply referred to below as the coefficient of expansion, amounts, in cadmium-telluride for example, to 5.9×10⁻⁶/K at 293 K, wherein that of nickel, with 13.4×10⁻⁶/K at 293 K, is much higher. CZT is an alloy of CdTe and ZnTe, wherein ZnTe typically has a smaller proportion of 5% to 10%. Therefore when the linear mixture rule is used as a basis, the coefficient of expansion of CZT lies very close to that of CdTe. Precise values for the coefficients of thermal expansion can be defined by the person skilled in the art in accordance with standard procedures or also found in technical literature.

In order to be used expediently as a solder resist layer, the metal A and the metal B or their mixture possess a melting point of preferably more than 150° C., further preferably of more than 160° C. and especially of 170° C. or higher. Typical soldering temperatures usually lie at around 200° C. The melting point of the solder resist layer should however lie at at least 300° C. in order to minimize temperature damage to the semiconductor elements or prevent it entirely. Generally it is true to say that the higher the melting point of the metals A and B used is, the greater flexibility there can be in selecting the solder material for the soldering process.

In accordance with a further form of embodiment of the inventive semiconductor material, the metal A is selected from the group of metals having a lower coefficient of expansion than the semiconductor material. Examples of such metals, which preferably at the same time have a higher melting point, include tungsten (4.5×10⁻⁶/K at 293 K), chrome (4.9×10⁻⁶/K at 293 K) and germanium (5.8×10⁻⁶/K at 293 K).

The metals A are used in accordance with a further form of embodiment with a metal B in a mixture, which is preferably selected from the group of metals which have a greater coefficient of expansion than the semiconductor material. Examples of such metals B, which preferably at the same time have a higher melting point, include nickel (13.4×10⁻⁶/K at 293 K), Copper (16.5×10⁻⁶/K at 293 K) and Titanium (8.6×10⁻⁶/K at 293 K).

In accordance with a preferred form of embodiment of the inventive semiconductor element, the metals A and B lie in a mixture ratio, so that the coefficient of expansion of the mixture in the preferred case is equal to or at least very similar to the coefficient of expansion of the semiconductor material used. It also preferably deviates from the coefficient of expansion of the semiconductor material used by not more than 10% (±10%). For pure CdTe or CZT the coefficient of expansion of the solder resist layer thus preferably lies at around 5.3-6.5×10⁻⁶/K (at 293 K).

A mixture here is to be understood as the solder resist layer including an alloy of the two metals A and B, wherein optionally an alloy of a number of metals, with at least one metal A and at least one metal B in each case, can also be used. The coefficient of expansion of this alloy is preferably adapted in this case, as previously explained, to the coefficient of expansion of the respective semiconductor material used.

As an alternative to the use of an alloy as solder resist layer, this layer can also have a multilayer construction of alternating layers of metal A and metal B. Such a multilayer construction consisting of at least two layers, preferably of at least two layers of metal A end of metal B in each case, also preferably of a plurality, i.e. three or more layers of the respective material A or B. These are preferably arranged alternately in this case, wherein intermediate layers of other materials, for example including an alloy of metal A and metal B and optionally further metals, can be used. Also with such a multi-layer construction, a mixture ratio of the metals A and B is used as an example of the alloy, so that the overall coefficient of expansion of the solder resist layer is roughly identical to that of the semiconductor material used. The mixture ratio A/B is preferably set here via the corresponding layer thickness ratios.

By setting the corresponding mixture ratio of the metals A and B in the solder resist layer, on the one hand for example by the alloy proportion, on the other hand for example via the layer thickness of the respective layers, the differences of the coefficients of expansion of the connection points of the semiconductor element to the UBM can be compensated for such that few or even no stresses at all arise both during application of the UBM and also during later operation. This prevents a degradation, i.e. a detaching of the metallization. Thus the inventive semiconductor elements, especially as a result of the improved soldering points, have an improved lifetime.

Equation 1 provides a general formula for the mixture ratio:

hl=x·a+(1−x)*b Eq. 1

with:
hl=Coefficient of expansion of the semiconductor
a=Coefficient of expansion of metal A
b=Coefficient of expansion of metal B
and wherein the following applies: a<hl and b>hl

Especially preferred quantities of the metals A lie at around 65-95% and those of the metal B at around 5-35% in relation to the overall mixture. Here a metal A or B can make up the mixture proportion or two or more metals A or B can make up these quantities together. For a temperature-stable UBM consisting of Tungsten and Titanium on CdTe an alloy with a mixture ratio W/Ti of around 2:1 is preferable. Further specific examples of preferred mixture combinations are given in Table 1 below.

TABLE 1

| | W | Cr | Ge | Ni | Ti | Cu | CdTe |
|---|---|---|---|---|---|---|---|
| Coefficient | 4.5 | 4.9 | 5.8 | 13.4 | 8.6 | 16.5 | 5.9 |
| of expansion | | | | | | | |
| [10⁻⁶/K] | | | | | | | |
| Optimum | | | | | | | |
| mixture [%] | | | | | | | |
| Example 1 | 66 | | | | 34 | | |
| Example 2 | | 73 | | | 27 | | |
| Example 3 | 84 | | | 16 | | | |
| Example 4 | | 88 | | 12 | | | |
| Example 5 | 91 | | | | | 9 | |
| Example 6 | 40 | 40 | | 10 | 10 | | |

The mixture ratios specified in the above table are specific preferred values from which there can be deviations of around 20%, preferably of around 10%, further preferably of around 5% without departing from the basic inventive idea.

In accordance with a preferred form of embodiment of the fabrication method of an inventive semiconductor element, a mixture of the metal A and B in the form of an alloy can be deposited on the connection points of the semiconductor element. Preferably this deposited alloy has a coefficient of expansion which deviates from the coefficient of expansion of the semiconductor material by not more than 10%, preferably by not more than 8%, further preferably by not more than 5%, especially by less than 3%. This enables stresses at the interfaces between the semiconductor element and the electronic components brought into contact therewith to be avoided or reduced.

During the application of alloy of A and B in the appropriate ratio an alloy with the mixture ratio A/B is preferably formed. This alloy is sputtered onto the semiconductor at the corresponding connection points of the semiconductor element, e.g. applied at room temperature, so that there is no separation of the mixture of A and B.

In an alternate form of embodiment, the solder resist layer including a number of alternating layers of metals A and B can be deposited on the respective connection points of the semiconductor material, and this can be done so that the solder resist layer has a coefficient of expansion which deviates from the coefficient of expansion of the semiconductor material by not more than 10%, preferably by not more than 8%, further preferably by not more than 5%, especially by less than 3%.

To embody a multilayer structure of metals A or B a vapor deposition process (or also a sputter process) is preferably used for deposition/application to the semiconductor. The individual layers are advantageously applied thinly enough for the stresses arising between the layers not to lead to delamination. A sufficient overall thickness of the layer is then achieved by a correspondingly high number of individual layers, without bringing with it the disadvantage of the thin layers in respect of a delamination. The layer thickness of the individual alternating layers of metals A or B is preferably selected so that the mixture ratio corresponds to a mixture ratio A/B, which has the same or essentially a similar coefficient of expansion as the semiconductor material used. Through the achieved overall thickness of the multilayer structure of the solder resist layer a sufficient thickness is achieved so that the layer does detach away during the soldering process. The solder resist layer thus achieved can be applied with almost any given thickness, so that a good separation between semiconductor and solder can be achieved. The simultaneous adaptation of the coefficient of expansion of semiconductor and UBM means that there are no longer stresses in the layer during temperature changes.

Accordingly, at least one embodiment of the inventively fabricated solder resist layers, in respect of the thickness and the temperature stability as well as in respect of the occurrence of stresses during temperature changes, satisfy the requirements for a plurality of usable solder materials.

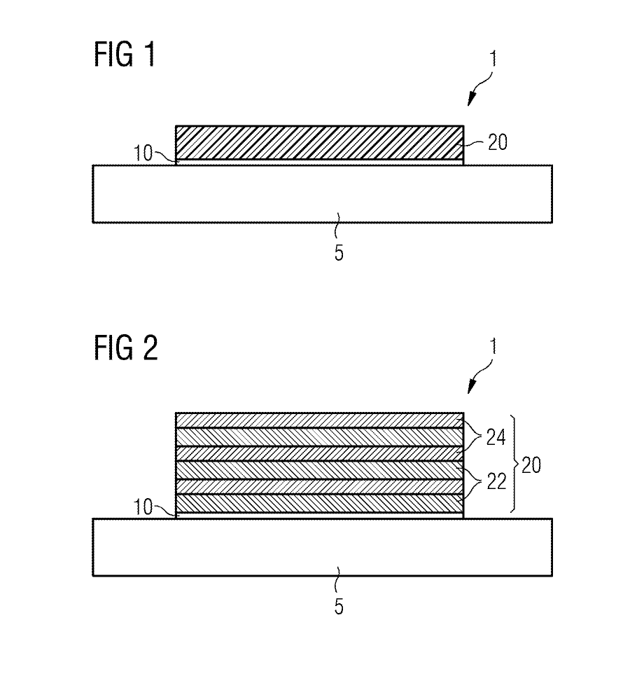

FIG. 1 illustrates a semiconductor element 1 with a connection point 10. At the connection point 10 an alloy of the metals A and B is applied as a single solder resist layer 20. The solder resist layer 20 serves as a connection between the semiconductor element 10 and an electronic component (not shown) via a solder connection.

FIG. 2 illustrates a semiconductor element 1 with a connection point 10, wherein a multilayer solder resist layer 20 is applied here. The solder resist layer 20 includes alternately layers 22 of the metal A and layers 24 of the metal B. The mixture ratio A/B in this case is determined by the thickness of the layers 22 and 24. In this example the layer thickness of the individual layers lies at a few micrometers, but depending on the field of application, can also amount to just a few atomic layers or have a greater thickness.

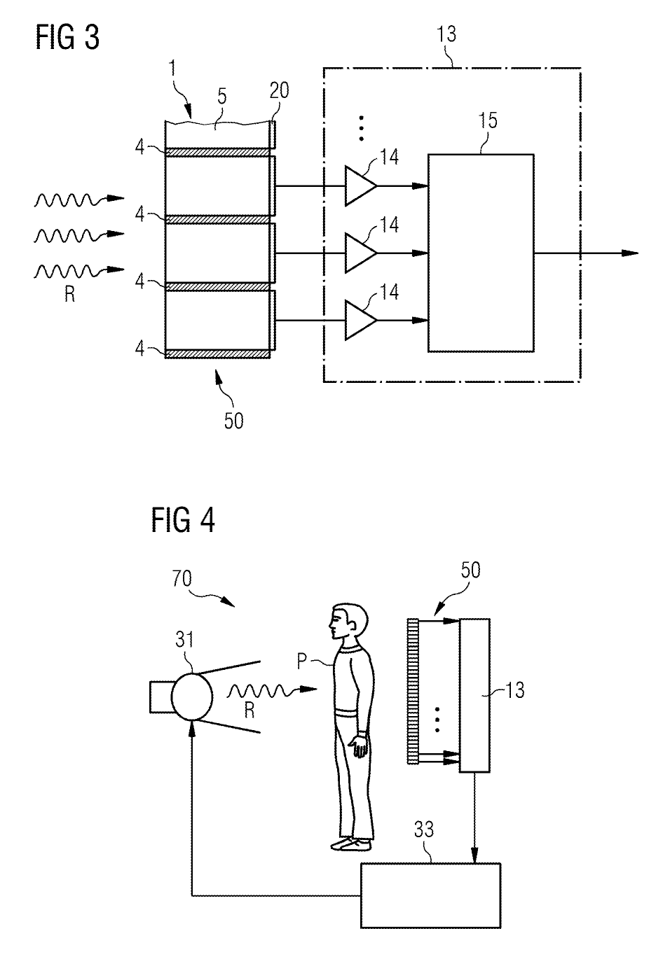

FIG. 3 shows an example embodiment for an inventive radiation detector 50, which is equipped here with evaluation electronics 13. To embody the detector, inventive semiconductor elements 1 with a semiconductor material 5 and a solder resist layer 20 are disposed in the form of a matrix next to one another and separated from one another by septa 4. The ionizing radiation to be detected, e.g. x-ray radiation R, strikes the semiconductor element 1 here. Basically, an inventive radiation detector of an embodiment can also be embodied so that the radiation R to be detected falls on the radiation detector from another incident direction.

The radiation detector 50 is provided here with evaluation electronics 13 which have a preamplifier 14 for each semiconductor element 1 in order to initially preamplify a signal arising in this semiconductor element 1. The preamplifier 14 is coupled to the semiconductor element 1 via the solder resist layer 20 and is shown in very simplified form in FIG. 3. The basic methods of how signals can be read out and further processed by a radiation detector are known to the person skilled in the art. The preamplifiers 14 are connected to a signal processing device 15, in which the signals are further processed and then for example forwarded to an evaluation unit (not shown).

FIG. 4 shows a very simple example embodiment for a medical technology device 70, here an x-ray system. This has an x-ray emitter 31, an embodiment of an inventive radiation detector 50 with evaluation electronics 13 and also a system control device 33. The x-ray emitter 31 and the x-ray detector 50 are arranged opposite one another in operation so that the direction of the radiation of the x-ray emitter 31 points in the direction of the radiation detector 50. An object under examination P, for example a patient or a part of the patient's body, is then positioned appropriately between the x-ray emitter 31 and the radiation detector 50 in order to acquire an x-ray image with the radiation detector 50 of the locally-resolved x-ray radiation R emitted by the x-ray emitter 31 and attenuated by the object under examination P. The x-ray emitter 31 is activated here by means of a system control device 33, shown greatly simplified, which also accepts detector signals processed by the evaluation electronics 13 for further processing, in order for example to reconstruct an image from the detector signals and output it to a user or store it in a memory.

It is finally pointed out once again that the semiconductor elements, radiation detectors, medical technology devices and methods for creating semiconductor elements described above merely involve preferred example embodiments which can be modified by the person skilled in the art in any given way without departing from the scope of the invention, provided said way is specified in the claims.

In particular the same or at least similar effects can be achieved if a UBM is merely used at a few connection points of such semiconductor element. In addition an embodiment of the general inventive concept and especially the advantage of matching the coefficient of expansion to the solder resist layer can also be transferred to other semiconductor elements. Therefore an embodiment of the invention also includes a method for creating a solder resist layer, for example in a fabrication process for semiconductor elements. How such a method is designed emerges from the descriptions of the fabrication method for semiconductor elements given above. For reasons of completeness it is also pointed out that the use of the indefinite article “a” or “an” does not preclude the features involved also being able to be present a number of times, likewise the term “element” as component does not exclude said element consisting of a number of components which may also be spatially distributed.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A semiconductor element, comprising:
a CdTe-based semiconductor material; and
a number of connection points for connection to electronic components, wherein the connection points including a solder resist layer comprising a mixture of at least two metals with different coefficients of expansion.

2. The semiconductor element of claim 1, wherein the semiconductor material is made up of semiconductor compounds selected from the group consisting of:
CdTe,
CdₓZn₁₋ₓTe (with 0≦x≦1),
CdₓZn₁₋ₓTe_{y}Se_{1-y} (with 0≦x≦1; 0≦y≦1), and
CdₓMn₁₋ₓTe_{y}Se_{1-y} (with 0≦x≦1; 0≦y≦1).

3. The semiconductor element of claim 1, wherein one of the at least two metals is selected from a group of metals which have a relatively lower coefficient of expansion than the semiconductor material.

4. The semiconductor element of claim 1, wherein one of the at least two metals is selected from a group of metals which have a relatively higher coefficient of expansion than the semiconductor material.

5. The semiconductor element of claim 1, wherein the solder resist layer consists of an alloy of exactly two metals.

6. The semiconductor element of claim 1, wherein the solder resist layer includes a multilayer structure of alternating layers of the at least two metals.

7. The semiconductor element of claim 1, wherein at least one of the at least two metals, or its mixture, has a melting point of more than 150° C.

8. A radiation detector, comprising:
a number of the semiconductor elements of claim 1.

9. A medical technology device comprising the radiation detector of claim 8.

10. A method for creating a semiconductor element including a CdTe-based semiconductor material and a number of connection points to electronic components, comprising:
applying a solder resist layer to the connection points, the solder resist layer including a mixture of at least two metals with different coefficients of expansion.

11. The method of claim 10, wherein the mixture of the metals is deposited in the form of an alloy as the solder resist layer, including a coefficient of expansion which deviates from a coefficient of expansion of the semiconductor material by not more than 10 percent.

12. The method as of claim 10, wherein the solder resist layer, including a number of alternating layers of the at least two metals, is deposited and wherein the solder resist layer includes a coefficient of expansion which deviates from a coefficient of expansion of the semiconductor material by not more than 10 percent.

13. The semiconductor element of claim 2, wherein one of the at least two metals is selected from a group of metals which have a relatively lower coefficient of expansion than the semiconductor material.

14. The semiconductor element of claim 2, wherein one of the at least two metals is selected from a group of metals which have a relatively higher coefficient of expansion than the semiconductor material.

15. The semiconductor element of claim 2, wherein the solder resist layer consists of an alloy of exactly two metals.

16. The semiconductor element of claim 2, wherein the solder resist layer includes a multilayer structure of alternating layers of the at least two metals.

17. The semiconductor element of claim 3, wherein one of the at least two metals is selected from a group of metals which have a relatively higher coefficient of expansion than the semiconductor material.

18. The radiation detector of claim 8, further comprising:
evaluation electronics, configured to read out a detector signal.

19. A medical technology device comprising the radiation detector of claim 18.
